(19) United States
(12) Patent Application Publication
(10) Pub. No.: US 2022/0320387 A1
(43) Pub. Date: Oct. 6, 2022

(54) OPTOELECTRONIC COMPONENT

(71) Applicant: OSRAM Opto Semiconductors GmbH, Regensburg (DE)

(72) Inventors: Daniel RICHTER, Bad Abbach (DE); Brendan HOLLAND, Regensburg (DE)

(21) Appl. No.: 17/624,816

(22) PCT Filed: Jun. 25, 2020
(86) PCT No.: PCT/EP2020/067911

§ 371 Date: Jan. 4, 2022

(30) Foreign Application Priority Data
Jul. 11, 2019 (DE) 10 2019 118 793.1

(51) Int. Cl. H01L 33/58; H01L 33/60; H01L 33/62; G02B 5/22; H01S 5/0232; C09K 11/06; C09K 11/02

(52) U.S. Cl. CPC H01L 33/58; H01L 33/60; H01L 33/62; G02B 5/223; H01S 5/0232; C09K 11/06; C09K 11/02; C09K 2211/188; C09K 2211/1029; C09K 2211/1007

(57) ABSTRACT

An optoelectronic component is specified comprising: at least one radiation-emitting semiconductor chip (1) which during operation emits electromagnetic radiation of a first wavelength range, and an absorber, wherein the absorber is predominantly transmissive to the emitted electromagnetic radiation of the first wavelength range, and the absorber absorbs at least 70% of the total radiation intensity of the electromagnetic spectrum of the visible light of the ambient light.

This application is a 35 U.S.C. § 371 National Phase of PCT Application No. PCT/EP2020/067911, filed Jun. 25, 2020, which claims priority to DE Application No. 10 2019 118 793.1 filed Jul. 11, 2019, the disclosures of which are hereby incorporated by reference in their entireties.

An optoelectronic component is specified.

An object to be solved is to specify an optoelectronic component that enables improved contrast perception.

Optoelectronic components can comprise at least one semiconductor chip that emits electromagnetic radiation in a specific wavelength range. For example, the optoelectronic component is an optoelectronic semiconductor laser component or a light-emitting diode.

According to at least one embodiment, the optoelectronic component comprises at least one radiation-emitting semiconductor chip that emits electromagnetic radiation of a first wavelength range during operation. The radiation-emitting semiconductor chip, such as a light-emitting diode chip and/or a laser diode chip, comprises an epitaxially grown semiconductor layer sequence with an active zone configured to generate electromagnetic radiation. For example, the radiation-emitting semiconductor chip may emit electromagnetic radiation from a wavelength range of ultraviolet radiation, visible light, and/or infrared radiation during operation. At least two radiation-emitting semiconductor chips may be introduced side by side into the optoelectronic component, emitting electromagnetic radiation of different wavelength ranges.

According to at least one embodiment, the optoelectronic component comprises an absorber. The absorber is adapted, for example, to transmit electromagnetic radiation of a specific, predeterminable wavelength range on the one hand and to absorb electromagnetic radiation of another specific, predeterminable wavelength range on the other hand. The absorber is adapted, for example, as a layer or in a layer that surrounds and/or covers the semiconductor chip in places. For example, several absorbers may also be introduced into the optoelectronic component.

According to at least one embodiment, the absorber is predominantly transmissive for the emitted electromagnetic radiation of the first wavelength range. Predominantly transmissive means that a major part of the emitted electromagnetic radiation of the first wavelength range of the semiconductor chip is not absorbed, but is transmitted by the absorber.

According to at least one embodiment, the absorber absorbs at least 70% of the total radiation intensity of the electromagnetic spectrum of the visible light of the ambient light under illumination with ambient light. Preferably, under illumination with ambient light, the absorber absorbs at least 80% of the radiation intensity of the electromagnetic spectrum of the visible light of the ambient light. The ambient light is generated from an electromagnetic spectrum of light of a plurality of colors that mix to form white light. The ambient light comprises a continuous spectrum or a quasi-continuous spectrum. In particular, the ambient light is not composed of two or three colors. In the present context, ambient light is understood to be, for example, sunlight and/or light from an incandescent lamp. The ambient light is preferably sunlight. The absorber appears black when illuminated with the ambient light.

The absorber is configured to absorb most of the light incident from the ambient light that is not transmitted by the absorber. This results in a portion of the ambient light being absorbed by the absorber and not being reflected, for example, at a mirror covered by the absorber. As a result, an impression of black is achieved, which enables improved contrast perception.

Advantageously, electromagnetic radiation of the wavelength range of the visible light of the ambient light is thus prevented from being reflected by the reflective components of the optoelectronic component, which would result in a reduced contrast. The reflective components of the optoelectronic component are purposefully covered with the absorber and thus reflection of the electromagnetic radiation of the wavelength range of the visible light of the ambient light is partially prevented.

According to at least one embodiment, the optoelectronic component comprises a radiation-emitting semiconductor chip which, in operation, emits electromagnetic radiation of a first wavelength range, and an absorber, wherein the absorber is predominantly transmissive to the emitted electromagnetic radiation of the first wavelength range, and the absorber absorbs, under illumination with ambient light, at least 70% of the total radiation intensity of the electromagnetic spectrum of the visible light of the ambient light.

One idea of the present optoelectronic component is to introduce an absorber into an optoelectronic component to advantageously suppress the reflection from the ambient light incident on the optoelectronic component. Thus, an improved contrast is achieved. Furthermore, the emitted electromagnetic radiation of the first wavelength range of the semiconductor chip is predominantly transmitted by the absorber. This radiation can then be reflected, for example. This increases the efficiency of the device.

According to at least one embodiment, the absorber absorbs at most 50% of the emitted radiation of the first wavelength range of the semiconductor chip. In operation, part of the emitted electromagnetic radiation of the first wavelength range of the semiconductor chip is reflected back towards the semiconductor chip, for example at the radiation exit side of the optoelectronic component. Advantageously, the electromagnetic radiation of the first wavelength range of the semiconductor chip is then absorbed by the absorber only to a maximum of 50% and the remainder, which is not absorbed, can be reflected out of the component.

According to at least one embodiment, the absorber absorbs at most 25% of the emitted electromagnetic radiation of the first wavelength range of the semiconductor chip. Due to the good transmission of the electromagnetic radiation of the first wavelength range of the semiconductor chip, a loss of brightness is reduced compared to an absorber that absorbs light regardless of the wavelength.

According to at least one embodiment, the optoelectronic component comprises three semiconductor chips. In operation, the three semiconductor chips emit electromagnetic radiation in the first wavelength range, in a second wavelength range and in a third wavelength range.

The three wavelength ranges are each different from one another. For example, light of three different colors, for example red, green and blue, is emitted.

The absorber is predominantly transmissive to the emitted electromagnetic radiation in the first wavelength range, in the second wavelength range, and in the third wavelength range of the semiconductor chips.

For example, the first wavelength range is in the electromagnetic spectrum between 610 nanometers and 700 nanometers, preferably between 610 nanometers and 640 nanometers. The second wavelength range is, for example, between 490 nanometers and 560 nanometers, and the third wavelength range is, for example, between 430 nanometers and 490 nanometers in the electromagnetic spectrum of visible light. A wavelength range of a particular color preferably comprises a bandwidth of at least 10 nanometers to at most 25 nanometers.

According to at least one embodiment, the absorber comprises an absorbing material and a matrix material. The absorbing material is a material that predominantly transmits the electromagnetic radiation of the first wavelength range of the semiconductor chip and additionally absorbs, under illumination with the ambient light, at least 70% of the total radiation intensity of the electromagnetic spectrum of the visible light of the ambient light.

The matrix material used is, for example, a silicone, an epoxy or a hybrid material. The matrix material preferably comprises at least 10 wt % and at most 70 wt % of the absorbing material. Particularly preferably, the matrix material comprises at least 30% by weight and at most 70% by weight of the absorbing material. The absorber is formed, for example, as a layer. The layer comprises a thickness of at least 500 nanometers to at most 5 micrometers. Preferably, the layer comprises a thickness of at least 1 micrometer to at most 3 micrometers.

According to at least one embodiment, the absorber comprises at least two absorbing materials and the matrix material. Preferably, the absorbing materials are different. Thus, with advantage, the transmittance for the electromagnetic radiation of the wavelength ranges of the semiconductor chips can be selectively adjusted. Particularly preferably, the absorber comprises absorbing materials that are predominantly transmissive for the first wavelength range, the second wavelength range and the third wavelength range of the semiconductor chip.

According to at least one embodiment, the absorbing material is or comprises a chromophore. A chromophore is any portion of a dye or pigment that makes its coloration possible. Preferably, organic chromophores comprising n-conjugated double bonds are used as absorbing material. Examples of organic chromophores used herein are:
long chains of conjugated double bonds, such as in carotene or chlorophyll,
azo groups linked aromatic compounds, such as in the azo dye methyl orange,
quinoid systems such as triarylmethane dyes alizarin, fuchsin or phenolphthalein,
nitro compounds such as aromatic nitro dyes picric acid. n-conjugated double bonds are double bonds that comprise a sequence of one double bond, one single bond, one double bond, one single bond. The n-conjugated double bonds achieve mesomeric resonance structures, which are responsible for the absorption properties and coloration inter alia.

According to at least one embodiment, the absorbing material is or comprises an organic semiconductor. The organic semiconductor is a semiconductor based on an organic material. Organic semiconductors can be divided into two classes by the criterion of the molar mass. One is the n-conjugated molecules and the other is the n-conjugated polymers. As n-conjugated molecules, the absorbing material used presently is in particular at least one of the following materials:
linear-fused ring systems, for example oligoacene such as anthracene, pentacene and its derivatives or benzenethiolate,
two-dimensional fused ring systems, for example perylene, PTCDA and its derivatives, naphthalene derivatives and hexabenzocorones,
metal complexes, for example phthalocyanine,
dendritic molecules, for example 4,4′,4″-tris(N,N-diphenyl-amino)triphenylamine (TDATA),
heterocyclic oligomers, for example oligothiophene, oligophenylenevinylene).

As n-conjugated polymers, inter alia heterocyclic polymers and hydrocarbon chains can be used. Heterocyclic polymers are for example polythiophene, polyparaphenylene, polypyrrole, polyaniline. Hydrocarbon chains are for example polyacetylene and polysulfur nitride.

Presently, the absorbing material comprises inter alia n-conjugated molecules and/or n-conjugated polymers.

Organic semiconductors are presently particularly advantageous as absorbing material because they can absorb a relatively narrow bandwidth and furthermore the absorption wavelengths can be adjusted by adjustments of the functional groups, for example by substituents of a basic structure. Furthermore, the organic semiconductors exhibit high stability, which is advantageous in the optoelectronic component due to high temperatures.

According to one embodiment, the absorbing material comprises a ligand comprising a porphyrin derivative. The porphyrin derivative is an organic chemical dye comprising four pyrrole rings cyclically linked by four methine groups. The carbon atoms of the pyrrole rings are substituted, for example. Substituents of the pyrrole rings are, for example, substituted and unsubstituted alkyl groups, substituted and unsubstituted aryl groups, substituted and unsubstituted alkenyl groups, substituted and unsubstituted cycloalkyl groups, substituted and unsubstituted heterocycloalkyl groups, substituted and unsubstituted heteroaryl groups. Each porphyrin derivative comprises n-conjugated double bonds. Notably, the porphyrin derivative is not an azaporphyrin. That is, the pyrrole rings are not linked by an imine group, R₁—N═CH—R₂.

According to at least one embodiment, the carbon atom of the methine group of the porphyrin derivative is substituted. For example, a benzene substituent or a substituted benzene substituent may be used as the substituent here.

According to at least one embodiment, the porphyrin derivative comprises the general formula:

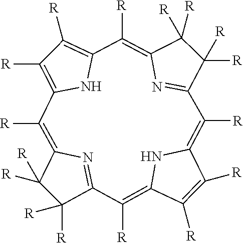

wherein R is independently selected from the group consisting of substituted and unsubstituted aryl substituents, substituted and unsubstituted alkyl substituents, substituted and unsubstituted alkenyl substituents, substituted and unsubstituted cycloalkyl substituents, substituted and unsubstituted heterocycloalkyl substituents, substituted and unsubstituted heteroaryl substituents, hydrogen, and combinations thereof, or wherein between two adjacent —CR₂—CR₂— the C atoms are unsaturated. That is, between two adjacent Rs, such as —CR₂—CR₂—, a double bond, such as —CR═CR—, is formed.

By varying the substituents R and combining different absorbing materials, the transmittance for the wavelength ranges of the electromagnetic radiation of the semiconductor chips can be adjusted particularly precisely. For example, an electron-withdrawing substituent is selected as substituent R. As a result, the predominant transmission of electromagnetic radiation in the first, red wavelength range is achieved. Advantageously, by combining a plurality of porphyrin derivatives with different substituents R as the absorbing material, the transmittance of electromagnetic radiation of the wavelength ranges of the semiconductor chips is controlled.

Examples of porphyrin derivatives as absorbing material are shown in the following:

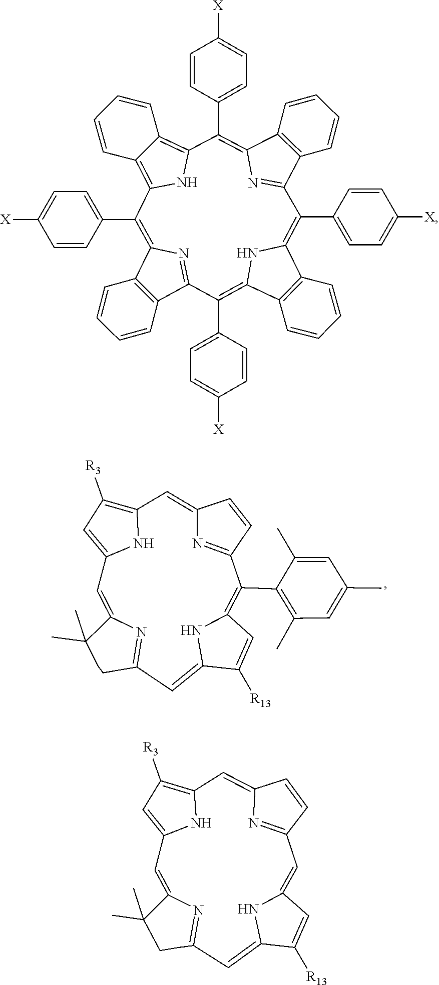

X may be independently selected from the group of hydrogen atoms or halogen atom. In particular, X is selected from the following group: H, Br, F, Cl, I. Preferably, X is a hydrogen atom or a bromine atom. R₃ and R₁₃ may be independently selected from the group consisting of substituted or unsubstituted alkyl groups. For example, R₃ is a propyl group and R₁₃ shows, for example, 13 C atoms, which are strung together saturated or unsaturated.

According to at least one embodiment, the absorbing material is or comprises a zinc complex. Preferably, nitrogen atoms coordinate to the zinc ion. Preferably, a porphyrin derivative is used as the ligand. Here, the N atoms of the pyrrole rings coordinate to the zinc ion. The zinc complex is able to be predominantly transmissive to the electromagnetic radiation in the green wavelength range of the semiconductor chip. For example, by varying from the metal ion zinc to another metal ion, the predominant transmittance to a wavelength range of visible light is adjusted.

According to at least one embodiment, the absorbing material comprises a ligand comprising a porphyrin derivative and a zinc ion as the central metal.

As a zinc complex, for example, one of the following complexes is used:

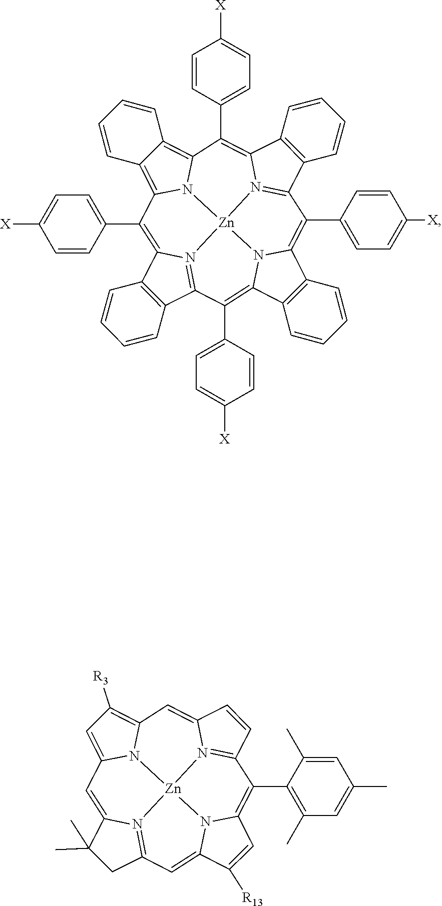

The residues X, R₃ and R₁₃ are already defined above. Preferably, the absorber comprises a zinc complex and a porphyrin derivative as absorbing material.

According to at least one embodiment, the optoelectronic component comprises a reflective leadframe or carrier. The reflective leadframe is, for example, a solderable metallic leadframe in the form of a frame or comb for machine fabrication of semiconductor chips or other electronic components. Preferably, the leadframe is connected to the semiconductor chip via bonding wires. Preferably, the leadframe is applied to an insulating carrier or to an insulating package. The semiconductor chip is then applied to the leadframe. The leadframe comprises a metal and is adapted to be reflective.

According to at least one embodiment, the semiconductor chip is embedded in a potting. The potting preferably comprises a silicone, epoxy or hybrid material. Preferably, the potting comprises the same material as the matrix material of the absorber. Preferably, the semiconductor chip is laterally surrounded by the potting. Particularly preferably, the semiconductor chip is laterally completely surrounded by the potting.

According to at least one embodiment, the semiconductor chip and the absorber are applied directly adjacent to each other on the leadframe or the carrier, so that the absorber is arranged between the potting and the leadframe or the carrier. That is, the absorber is arranged as a thin layer on the leadframe or carrier adjacent to the semiconductor chip. Alternatively, the absorbing material may be arranged directly as particles on the leadframe or carrier.

According to at least one embodiment, the semiconductor chip is embedded in a potting and the semiconductor chip and the absorber are applied directly adjacent to each other on the leadframe or carrier such that the absorber is arranged between the encapsulant and the leadframe or carrier.

According to at least one embodiment, the absorber is introduced into the potting. For example, the absorber is introduced into the potting as a layer and/or the absorbing material of the absorber is introduced into the potting in the form of particles. The matrix material of the absorber and the potting preferably comprise the same material or the potting forms the matrix material into which the absorbing material is introduced.

According to at least one embodiment, a coating material surrounds the potting and the semiconductor chip, and the absorber is applied to the potting such that the absorber is arranged between the potting and the coating material. The coating material is preferably a silicone, epoxy or hybrid material. The coating material comprises, for example, a different material than the potting and/or than the matrix material of the absorber. The absorber is applied as a layer to the potting and/or the absorbing material is arranged as particles on the potting.

According to at least one embodiment, the absorber is applied on the potting. Here, preferably, the absorber is applied as a layer on the potting.

According to at least one embodiment, the absorber covers the semiconductor chip at least in places. That is, the absorber as a layer and/or the absorbing material as particles is applied on the semiconductor chip at least in places. This is possible because the absorber comprises a high transmittance for the light emitted from the semiconductor chip during operation. In addition, the side surfaces of the semiconductor chip can be coated with the absorber without resulting in a loss of brightness.

In a fabrication of the optoelectronic component, the absorber and/or the absorbing material are preferably sprayed onto the potting, onto the leadframe, onto the carrier and/or into the potting. Additionally or optionally, the absorber may be introduced into a housing surrounding the semiconductor chip and the potting. Further, the absorber may be introduced into the coating material that is applied on the potting.

The absorber may also be introduced into or onto all of the components, that is, into the potting, onto the potting, onto the leadframe, onto the carrier, into the housing, and/or into the coating material.

According to at least one embodiment, the coating material comprises scattering particles. The scattering particles are adapted in the form of nanoparticles. Preferably, the scattering particles are selected from the following group: TiO₂, SiO₂, ZrO₂, Al₂O₃, BaTiO₃, SrTiO₃, TCO (transparent conductive oxides), Nb₂O₅, HfO₂, ZnO.

One idea of the present optoelectronic component is to suppress the reflection of ambient light at the leadframe or carrier by adding an absorber. This results in a very good contrast and black impression.

Furthermore, the absorber described here predominantly transmits the emitted electromagnetic radiation of the semiconductor chip. This makes for a particularly efficient device with good contrast.

In optoelectronic components with conventional absorbers, a good black impression is achieved, but at the expense of brightness. Here, an absorber material is used that almost completely absorbs the electromagnetic radiation of the visible light of the ambient light. However, the conventional absorber material also absorbs the electromagnetic radiation of the wavelength range of the semiconductor chip almost completely and is not predominantly transmissive to the electromagnetic radiation of the wavelength range of the semiconductor chip.

An optoelectronic component described herein can be used with particular advantage as a pixel in a video screen, a TV apparatus, a monitor or other optical display apparatus.

Further advantageous embodiments and further embodiments of the optoelectronic component are apparent from the exemplary embodiments described below in conjunction with the figures.

It shows:

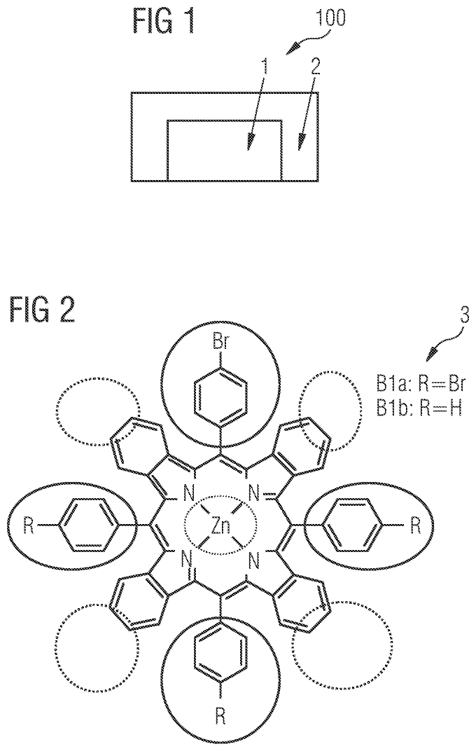

FIG. 1 a schematic sectional view of an optoelectronic component according to an exemplary embodiment,

FIG. 2 a chemical structural formula of a zinc complex,

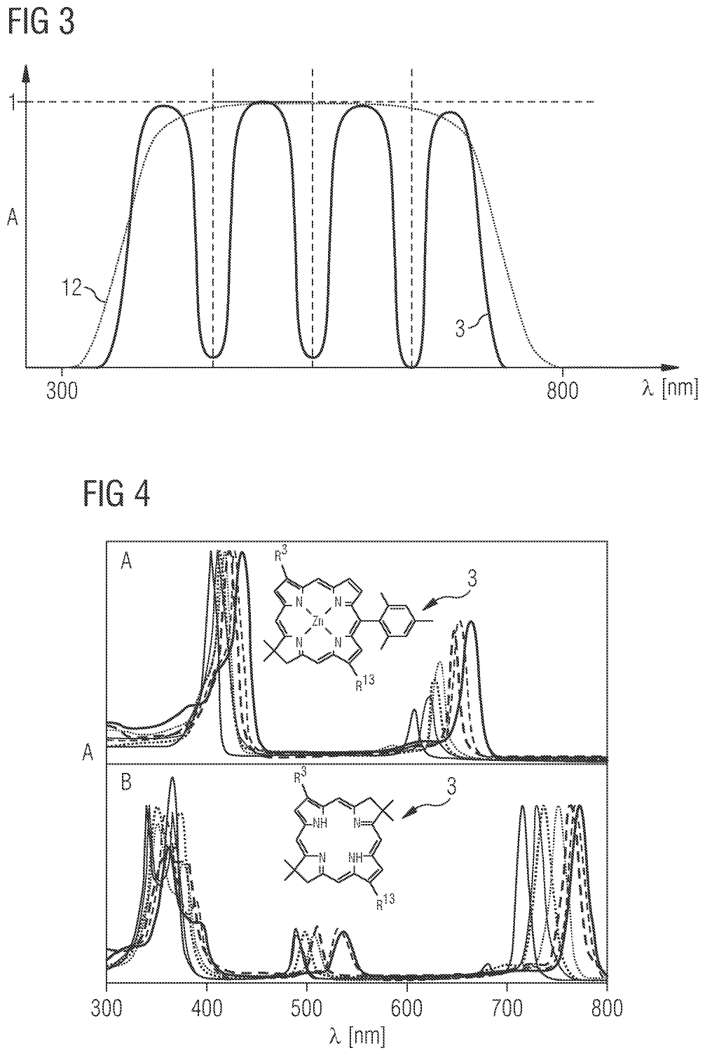

FIGS. 3, 4 and 5 absorption spectra of the absorbing material in the wavelength range from 300 to 800 nanometers, each according to an exemplary embodiment,

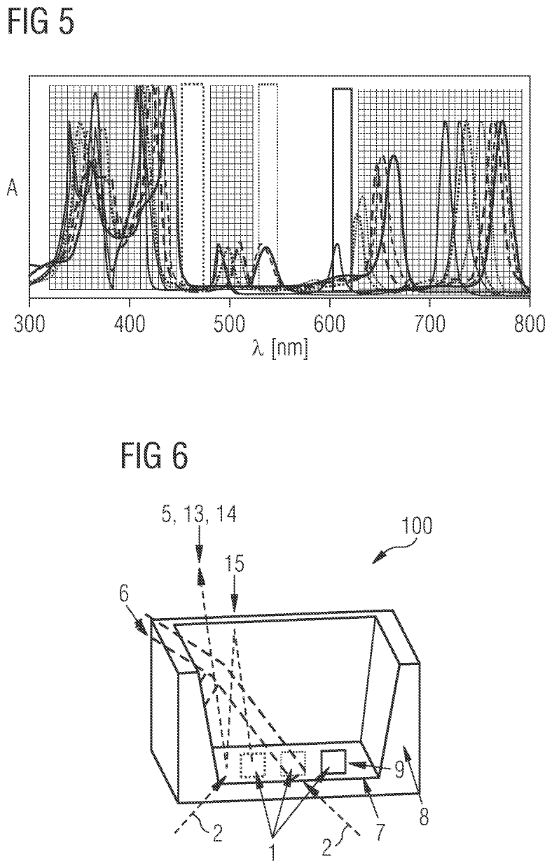

FIG. 6 a schematic sectional view of an optoelectronic component in a housing with three semiconductor chips according to an exemplary embodiment,

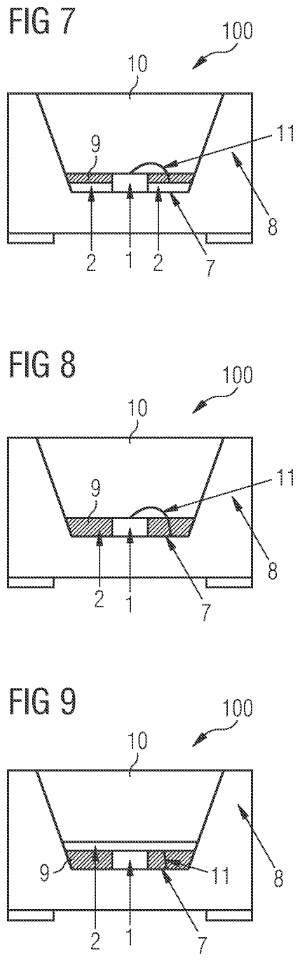

FIGS. 7, 8 and 9 each a schematic sectional view of an optoelectronic component with a potting, a leadframe, and a coating material according to an exemplary embodiment.

Elements that are identical, of the same type or have the same effect are provided with the same reference signs in the figures. The figures and the proportions of the elements shown in the figures with respect to one another are not to be regarded as to scale. Rather, individual elements, in particular layer thicknesses, may be shown exaggeratedly large for better representability and/or better understanding.

The optoelectronic component 100 according to the exemplary embodiment of FIG. 1 comprises a semiconductor chip 1, which emits electromagnetic radiation of a first wavelength range 5 during operation, and an absorber 2. The absorber 2 is, for example, applied to the semiconductor chip 1 and/or arranged adjacent to the semiconductor chip 1. The absorber 2 comprises at least an absorbing material 3 and a matrix material. The absorbing material 3 is or comprises, for example, a chromophore and/or an organic semiconductor. The matrix material is for example an epoxy, silicone or hybrid material.

The absorber 2 is predominantly transmissive for the emitted electromagnetic radiation of the first wavelength range 5. With predominantly transmissive is meant that the electromagnetic radiation of the first wavelength range 5 of the semiconductor chip 1 is absorbed to at most 50%. Preferably, the emitted electromagnetic radiation of the first wavelength range 5 of the semiconductor chip 1 is absorbed by the absorber 2 to at most 25%.

Further, the absorber 2 appears black under illumination with ambient light 6. The ambient light 6 is generated from an electromagnetic spectrum of a plurality of colors which mix to form white light. Ambient light 6 is understood to mean, in particular, sunlight. The absorber 2 absorbs at least 70% of the radiation intensity of the visible light of the ambient light 6. That is, the absorber 2 is adapted to absorb most of the wavelength ranges of the visible light of the ambient light 6 under illumination and to transmit most of the emitted electromagnetic radiation of the first wavelength range 5 of the semiconductor chip 1. Furthermore, the absorber 2 predominantly transmits the wavelength range of the ambient light 6 corresponding to the wavelength range of the semiconductor chip 1.

The chemical structural formula shown in FIG. 2 shows a zinc complex as absorbing material 3.

The zinc complex comprises a porphyrin ligand which predominantly transmits selected wavelength ranges by using different substituents. The different substituents are shown solid or dashed. Porphyrin derivatives as ligands are suitable as absorbing material 3 because they comprise a conjugated n-electron system and thus can be arbitrarily tuned by different substituents. If electron-withdrawing substituents, such as phenyl bromide, solid line, are used, then electromagnetic radiation in the first, red wavelength range is predominantly transmissive to the optoelectronic component 100. In addition to zinc metals, other metals can be used which have an influence on the absorption spectrum. Preferably, the absorber comprises at least two absorbing materials.

FIG. 3 shows exemplarily two absorption spectra of a conventional absorbing material 12 and an absorption spectrum of an absorbing material 3 described herein or an absorber 2 described herein with at least two absorbing materials 3. The absorption spectrum of an optoelectronic component 100 with a conventional absorbing material 12 is shown with a dotted line. The absorption spectrum of the optoelectronic component 100 according to the present invention is shown with a solid line.

The conventional absorbing material 12 shows almost complete absorption of the wavelength range in visible light from 300 nanometers to 800 nanometers. The absorber 2 of the optoelectronic component 100 preferably comprises at least two different absorbing materials 3. The absorbing materials 3 may comprise an identical backbone, for example a porphyrin derivative, wherein the substituents differ. By using different substituents, the absorption spectrum is adjusted. FIG. 3 shows that in the green, blue and red wavelength range, the absorber 2 is predominantly transmissive.

FIG. 4 shows two absorption spectra with different absorbing materials 3. The upper FIG. 4 shows a zinc complex as absorbing material 3 and the lower FIG. 4 shows an absorption spectrum with a porphyrin derivative ligand as absorbing material 3. Here, the zinc complex as well as the porphyrin derivative ligand comprise different substituents R. The different substituents R lead to different absorption spectra. The different substituents R lead to different absorption spectra. These are shown in the figures as dotted, solid, dashed, thin or thick lines. It can be seen from FIG. 4 that different absorbing materials 3 show different absorption of electromagnetic radiation of the wavelength range of visible light.

In FIG. 5, as in FIGS. 3 and 4, the absorption is plotted against the wavelength A. Two absorbing materials 3 were used as absorbers 2. It can be seen that the electromagnetic radiation in the blue, green and red wavelength range is almost completely transmitted. The other wavelength ranges of visible light are mostly absorbed by the absorbing material 3 from the absorber 2 of the optoelectronic component 100.

The optoelectronic component 100 of FIG. 6 according to an exemplary embodiment comprises three semiconductor chips 1. In operation, the semiconductor chips 1 emit electromagnetic radiation in the first wavelength range 5, in a second wavelength range 13, and in a third wavelength range 14. The semiconductor chip 1 that emits electromagnetic radiation in the first wavelength range 5 is shown with a solid line. The semiconductor chip 1 that emits electromagnetic radiation in the second wavelength range 13 is shown with a dotted line, and the semiconductor chip 1 that emits electromagnetic radiation in the third wavelength range 14 is shown with a thick dashed line. Here, the optoelectronic component 100 is introduced into a housing 8 and the semiconductor chips 1 are embedded side by side in a potting 9. The absorber 2 is located on the potting 9 and/or under the potting 9 and/or in the potting 9. The potting 9 comprises as material, for example, a silicone, epoxy or hybrid material. The potting 9 can comprise the same material as the matrix material of the absorber 2.

The semiconductor chips 1 are applied on a reflective leadframe 7. With advantage, the irradiated light of the ambient light 6 is mostly absorbed by the absorber 2 and not reflected by the reflective leadframe 7. The absorber 2 is further provided for predominantly transmitting the emitted electromagnetic radiation in the first wavelength range 5, in the second wavelength range 13 and in the third wavelength range 14. Furthermore, the absorber 2 predominantly transmits the wavelength ranges of the ambient light 6 corresponding to the wavelength ranges of the semiconductor chips 1. The emitted electromagnetic radiation of the semiconductor chips 1 is reflected at the radiation exit side 15 in the direction of the leadframe 7, and thus is mostly transmitted or reflected by the absorber 2 and not absorbed by the absorber 2.

The exemplary embodiment of FIG. 7 shows a housing 8 in which the semiconductor chip 1 is embedded in a potting 9. A coating material 10 is located on the potting 9 and on the semiconductor chip 1. The semiconductor chip 1 is applied on a reflective leadframe 7, which is connected to the semiconductor chip 1 via a bonding wire 11. The absorber 2 is applied on the leadframe 7 directly adjacent to the semiconductor chip 1, so that the absorber 2 is arranged between the potting 9 and the leadframe 7. The absorber 2 is adapted here as a layer.

The coating material 10 comprises a silicone, an epoxy or a hybrid material and may be different from the potting 9 or from the matrix material of the absorber 2. Furthermore, scattering particles are additionally embedded in the coating material 10, for example. The scattering particles are adapted as nanoparticles and can be selected from the following group: TiO₂, SiO₂, ZrO₂, Al₂O₃, BaTiO₃, SrTiO₃, TCO (transparent conductive oxides), Nb₂O₅, HfO₂, ZnO.

The exemplary embodiment of FIG. 8 differs from the exemplary embodiment of FIG. 7 in that the absorber 2 is embedded as a particle or layer in the potting 9.

The exemplary embodiment of FIG. 9 differs from the exemplary embodiments of FIG. 8 and FIG. 7 in that the absorber 2 is applied to the potting 9 so that the absorber 2 is arranged between the potting 9 and the coating material 10. The absorber 2 may here cover the semiconductor chip 1 at least in places.

The features and exemplary embodiments described in connection with the figures may be combined with each other in accordance with further exemplary embodiments, even though not all combinations are explicitly described. Furthermore, the exemplary embodiments described in connection with the figures may alternatively or additionally comprise further features according to the description in the general part.

The invention is not limited to the exemplary embodiments by the description based thereon. Rather, the invention encompasses any new feature as well as any combination of features, which in particular includes any combination of features in the patent claims, even if this feature or combination itself is not explicitly specified in the patent claims or exemplary embodiments.

This patent application claims priority to German patent application 10 2019 118 793.1, the disclosure content of which is hereby incorporated by reference.

### LIST OF REFERENCE SIGNS

100 optoelectronic component
1 semiconductor chip
2 absorber
3 absorbing material
5 first wavelength range
6 ambient light
7 leadframe
8 housing
9 potting
10 coating material
11 bonding wire
12 common absorbing material
13 second wavelength range
14 third wavelength range
15 radiation exit side

1. Optoelectronic component with
at least one radiation-emitting semiconductor chip which, in operation, emits electromagnetic radiation of a first wavelength range, and
an absorber, wherein
the absorber is predominantly transmissive to the emitted electromagnetic radiation of the first wavelength range, and
the absorber under illumination with ambient light absorbs at least 70% of the total radiation intensity of the electromagnetic spectrum of the visible light of the ambient light,
the absorber comprises an absorbing material and a matrix material,
the absorbing material comprises a ligand comprising a porphyrin derivative, and
the porphyrin derivative comprises the general formula 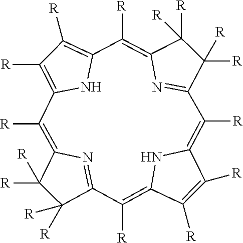
wherein R is independently selected from the group consisting of substituted and unsubstituted aryl substituents, substituted and unsubstituted alkyl substituents, substituted and unsubstituted alkenyl substituents, substituted and unsubstituted cycloalkyl substituents, substituted and unsubstituted heterocycloalkyl substituents, substituted and unsubstituted heteroaryl substituents, hydrogen, and combinations thereof, or wherein between two adjacent —CR₂—CR₂— the C-atoms are unsaturated.

2. Optoelectronic component according to claim 1,
in which the absorber absorbs at most 50% of the emitted electromagnetic radiation of the first wavelength range of the semiconductor chip.

3. Optoelectronic component according to claim 1,
in which the absorber absorbs at most 25% of the emitted electromagnetic radiation of the first wavelength range of the semiconductor chip.

4. Optoelectronic component according to claim 1,
in which the optoelectronic component comprises three semiconductor chips which, in operation, emit electromagnetic radiation in the first wavelength range, in a second wavelength range, and in a third wavelength range, wherein the absorber is predominantly transmissive to the emitted electromagnetic radiation in the first wavelength range, in the second wavelength range and in the third wavelength range of the semiconductor chips.

5. Optoelectronic component according to claim 1,
in which the absorber comprises at least two absorbing materials and the matrix material.

6. Optoelectronic component according to claim 1,
in which the absorbing material is or comprises an organic semiconductor.

7. Optoelectronic component according to claim 1,
in which the absorbing material is or comprises a Zn complex.

8. Optoelectronic component according to claim 1,
in which the optoelectronic component comprises a reflective leadframe.

9. Optoelectronic component according to claim 1,
in which the semiconductor chip is embedded in a potting, and
the semiconductor chip and the absorber are applied directly adjacent to one another on the leadframe, so that the absorber is arranged between the potting and the leadframe.

10. Optoelectronic component according to claim 1,
in which the absorber is introduced into the potting.

11. Optoelectronic component according to claim 1,
in which a coating material surrounds the potting and the semiconductor chip, and
the absorber is applied on the potting such that the absorber is arranged between the potting and the coating material.

12. Optoelectronic component according to claim 1,
in which the absorber is applied on the potting.

13. Optoelectronic component according to claim 1,
in which the absorber covers the semiconductor chip at least in places.

14. Optoelectronic component according to claim 1,
in which the absorbing material comprises a zinc complex.

15. Optoelectronic component according to claim 1,
in which the absorbing material comprises the ligand comprising the porphyrin derivative and a zinc ion as the central metal.

16. Optoelectronic component according to claim 1,
in which the porphyrin derivative is selected from the group of the following formulae: 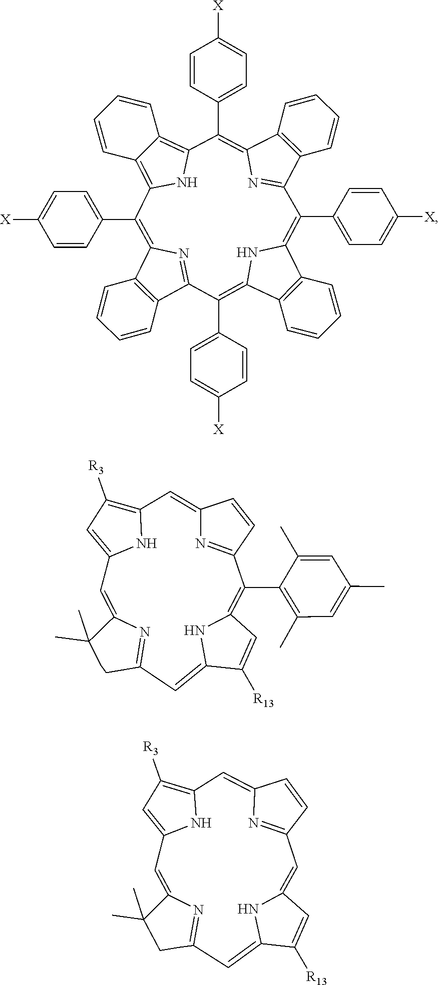
wherein X is independently selected from the group consisting of H, F, Br, Cl, I; and
R₃ and R₁₃ are independently selected from the group consisting of substituted and unsubstituted alkyl groups.
